(19) United States
(12) Patent Application Publication
(10) Pub. No.: US 2026/0128092 A1
(43) Pub. Date: May 7, 2026

(54) TEMPERATURE COMPENSATION FOR ANALOG MEMORY CELLS IN A NEURAL NETWORK

(71) Applicant: Silicon Storage Technology, Inc., San Jose, CA (US)

(72) Inventors: HOA VU, Milpitas, CA (US); STANLEY HONG, San Jose, CA (US); HIEU VAN TRAN, San Jose, CA (US); THUAN VU, San Jose, CA (US); STEPHEN TRINH, San Jose, CA (US)

(21) Appl. No.: 18/988,841

(22) Filed: Dec. 19, 2024

Related U.S. Application Data
(60) Provisional application No. 63/716,166, filed on Nov. 4, 2024.

(51) Int. Cl. G11C 11/54; G11C 16/04; G11C 16/08; G11C 16/14; G11C 16/26; H03M 1/66

(52) U.S. Cl. CPC G11C 11/54; G11C 16/0425; G11C 16/08; G11C 16/14; G11C 16/26; H03M 1/66

(57) ABSTRACT

In one example, a method comprises determining a bias voltage in response to a change in operating temperature of an array of non-volatile memory cells, each of the non-volatile memory cells in the array of memory cells comprising a control gate terminal and an erase gate terminal; and applying the bias voltage to a control gate terminal and an erase gate terminal of a selected memory cell in the array of memory cells while reading the selected memory cell.

### PRIORITY CLAIM

This application claims priority to U.S. Provisional Patent Application No. 63/716,166, filed on Nov. 4, 2024, and titled “Temperature Compensation for Analog Memory Cells in a Neural Network,” which is incorporated by reference herein.

### FIELD OF THE INVENTION

Numerous examples are disclosed for providing temperature compensation for analog memory cells used in a neural network.

### BACKGROUND OF THE INVENTION

Artificial neural networks mimic biological neural networks (the central nervous systems of animals, in particular the brain) and are used to estimate or approximate functions that can depend on a large number of inputs and are generally unknown. Artificial neural networks generally include layers of interconnected “neurons” which exchange messages between each other.

FIG. 1 illustrates an artificial neural network, where the circles represent the inputs or layers of neurons. The connections (called synapses) are represented by arrows and have numeric weights that can be tuned based on experience. This makes neural networks adaptive to inputs and capable of learning. Typically, neural networks include a layer of multiple inputs. There are typically one or more intermediate layers of neurons, and an output layer of neurons that provide the output of the neural network. The neurons at each level individually or collectively make a decision based on the received data from the synapses.

One of the major challenges in the development of artificial neural networks for high-performance information processing is a lack of adequate hardware technology. Indeed, practical neural networks rely on a very large number of synapses, enabling high connectivity between neurons, i.e., a very high computational parallelism. In principle, such complexity can be achieved with digital supercomputers or graphics processing unit clusters. However, in addition to high cost, these approaches also suffer from mediocre energy efficiency as compared to biological networks, which consume much less energy primarily because they perform low-precision analog computation. CMOS analog circuits have been used for artificial neural networks, but most CMOS-implemented synapses have been too bulky given the high number of neurons and synapses.

Applicant previously disclosed an artificial (analog) neural network that utilizes one or more non-volatile memory arrays as the synapses in U.S. Patent Application Publication 2017/0337466A1, which is incorporated by reference. The non-volatile memory arrays operate as an analog neural memory and comprise non-volatile memory cells arranged in rows and columns. The neural network includes a first plurality of synapses configured to receive a first plurality of inputs and to generate therefrom a first plurality of outputs, and a first plurality of neurons configured to receive the first plurality of outputs. The first plurality of synapses includes a plurality of memory cells, wherein each of the memory cells includes spaced apart source and drain regions formed in a semiconductor substrate with a channel region extending there between, a floating gate disposed over and insulated from a first portion of the channel region and a non-floating gate disposed over and insulated from a second portion of the channel region. Each of the plurality of memory cells store a weight value corresponding to a number of electrons on the floating gate. The plurality of memory cells multiply the first plurality of inputs by the stored weight values to generate the first plurality of outputs.

### Non-Volatile Memory Cells

Non-volatile memories are well known. For example, U.S. Pat. No. 5,029,130 (“the '130 patent”), which is incorporated herein by reference, discloses an array of split gate non-volatile memory cells, which are a type of flash memory cells. Such a memory cell 210 is shown in FIG. 2. Each memory cell 210 includes source region 14 and drain region 16 formed in semiconductor substrate 12, with channel region 18 there between. Floating gate 20 is formed over and insulated from (and controls the conductivity of) a first portion of the channel region 18, and over a portion of the source region 14. Word line terminal 22 (which is typically coupled to a word line) has a first portion that is disposed over and insulated from (and controls the conductivity of) a second portion of the channel region 18, and a second portion that extends up and over the floating gate 20. The floating gate 20 and word line terminal 22 are insulated from the substrate 12 by a gate oxide. Bitline 24 is coupled to drain region 16.

Memory cell 210 is erased (where electrons are removed from the floating gate) by placing a high positive voltage on the word line terminal 22, which causes electrons on the floating gate 20 to tunnel through the intermediate insulation from the floating gate 20 to the word line terminal 22 via Fowler-Nordheim (FN) tunneling.

Memory cell 210 is programmed by source side injection (SSI) with hot electrons (where electrons are placed on the floating gate) by placing a positive voltage on the word line terminal 22, and a positive voltage on the source region 14. Electron current will flow from the drain region 16 towards the source region 14. The electrons will accelerate and become heated when they reach the gap between the word line terminal 22 and the floating gate 20. Some of the heated electrons will be injected through the gate oxide onto the floating gate 20 due to the attractive electrostatic force from the floating gate 20.

Memory cell 210 is read by placing positive read voltages on the drain region 16 and word line terminal 22 (which turns on the portion of the channel region 18 under the word line terminal). If the floating gate 20 is positively charged (i.e., erased of electrons), then the portion of the channel region 18 under the floating gate 20 is turned on as well, and current will flow across the channel region 18, which is sensed as the erased or “1” state. If the floating gate 20 is negatively charged (i.e., programmed with electrons), then the portion of the channel region under the floating gate 20 is mostly or entirely turned off, and current will not flow (or there will be little flow) across the channel region 18, which is sensed as the programmed or “0” state.

Table No. 1 depicts typical voltage and current ranges that can be applied to the terminals of memory cell 210 for performing read, erase, and program operations:

TABLE NO 1
Operation of Flash Memory Cell 210 of FIG. 2

| | | |
|---|---|---|
| WL | BL | SL |

| | | | | | | |
|---|---|---|---|---|---|---|
| Read | 2-3 | V | 0.6-2 | V | 0 | V |
| Erase | ~11-13 | V | 0 | V | 0 | V |

| | | | | | |
|---|---|---|---|---|---|
| Program | 1-2 | V | 10.5- | 9-10 | V |
| | | | 3 μA | | |

Other split gate memory cell configurations, which are other types of flash memory cells, are known. For example, FIG. 3 depicts a four-gate memory cell 310 comprising source region 14, drain region 16, floating gate 20 over a first portion of channel region 18, a select gate 22 (typically coupled to a word line, WL) over a second portion of the channel region 18, a control gate 28 over the floating gate 20, and an erase gate 30 over the source region 14. This configuration is described in U.S. Pat. No. 6,747,310, which is incorporated herein by reference for all purposes. Here, all gates are non-floating gates except floating gate 20, meaning that they are electrically connected or connectable to a voltage source. Programming is performed by heated electrons from the channel region 18 injecting themselves onto the floating gate 20. Erasing is performed by electrons tunneling from the floating gate 20 to the erase gate 30.

Table No. 2 depicts typical voltage and current ranges that can be applied to the terminals of memory cell 310 for performing read, erase, and program operations:

TABLE NO 2
Operation of Flash Memory Cell 310 of FIG. 3

| | WL/SG | | BL | | CG | | EG | | SL | |
|---|---|---|---|---|---|---|---|---|---|---|
| Read | 1.0-2 | V | 0.6-2 | V | 0-2.6 | V | 0-2.6 | V | 0 | V |

| | | | | | | | | |
|---|---|---|---|---|---|---|---|---|
| Erase | −0.5 V/0 V | 0 | V | 0 V/−8 V | 8-12 | V | 0 | V |

| | | | | | | | | | |
|---|---|---|---|---|---|---|---|---|---|
| Program | 1 | V | 0.1- | 8-11 | V | 4.5-9 | V | 4.5-5 | V |
| | | | 1 μA | | | | | | |

FIG. 4 depicts a three-gate memory cell 410, which is another type of flash memory cell. Memory cell 410 is identical to the memory cell 310 of FIG. 3 except that memory cell 410 does not have a separate control gate. The erase operation (whereby erasing occurs through use of the erase gate) and read operation are similar to that of the FIG. 3 except there is no control gate bias applied. The programming operation also is done without the control gate bias, and as a result, a higher voltage is applied on the source line during a program operation to compensate for a lack of control gate bias.

Table No. 3 depicts typical voltage and current ranges that can be applied to the terminals of memory cell 410 for performing read, erase, and program operations:

TABLE NO 3
Operation of Flash Memory Cell 410 of FIG. 4

| | | | |
|---|---|---|---|
| WL/SG | BL | EG | SL |

| | | | | | | | | |
|---|---|---|---|---|---|---|---|---|
| Read | 0.7-2.2 | V | 0.6-2 | V | 0-2.6 | V | 0 | V |

| | | | | | | | |
|---|---|---|---|---|---|---|---|
| Erase | −0.5 V/0 V | 0 | V | 11.5 | V | 0 | V |

| | | | | | | | |
|---|---|---|---|---|---|---|---|
| Program | 1 | V | 0.2- | 4.5 | V | 7-9 | V |
| | | | 3 μA | | | | |

FIG. 5 depicts stacked gate memory cell 510, which is another type of flash memory cell. Memory cell 510 is similar to memory cell 210 of FIG. 2, except that floating gate 20 extends over the entire channel region 18, and control gate 22 (which here will be coupled to a word line) extends over floating gate 20, separated by an insulating layer (not shown). The erase is done by FN tunneling of electrons from FG to substrate, programming is by channel hot electron (CHE) injection at region between the channel 18 and the drain region 16, by the electrons flowing from the source region 14 towards to drain region 16 and read operation which is similar to that for memory cell 210 with a higher control gate voltage.

Table No. 4 depicts typical voltage ranges that can be applied to the terminals of memory cell 510 and substrate 12 for performing read, erase, and program operations:

TABLE NO 4
Operation of Flash Memory Cell 510 of FIG. 5

| | CG | BL | SL | Substrate |
|---|---|---|---|---|
| Read | 2-5 V | 0.6-2 V | 0 V | 0 V |
| Erase | −8 to −10 V/0 V | FLT | FLT | 8-10 V/15-20 V |
| Program | 8-12 V | 3-5 V | 0 V | 0 V |

The methods and means described herein may apply to other non-volatile memory technologies such as FINFET split gate flash or stack gate flash memory, NAND flash, SONOS (silicon-oxide-nitride-oxide-silicon, charge trap in nitride), MONOS (metal-oxide-nitride-oxide-silicon, metal charge trap in nitride), ReRAM (resistive ram), PCM (phase change memory), MRAM (magnetic ram), FeRAM (ferroelectric ram), CT (charge trap) memory, CN (carbon-tube) memory, OTP (bi-level or multi-level one time programmable), and CeRAM (correlated electron ram), without limitation.

In order to utilize the memory arrays comprising one of the types of non-volatile memory cells described above in an artificial neural network, two modifications are made. First, the lines are configured so that each memory cell can be individually programmed, erased, and read without adversely affecting the memory state of other memory cells in the array, as further explained below. Second, continuous (analog) programming of the memory cells is provided.

Specifically, the memory state (i.e., charge on the floating gate) of each memory cell in the array can be continuously changed from a fully erased state to a fully programmed state, and vice-versa, independently and with minimal disturbance of other memory cells. This means the cell storage is effectively analog or at the very least can store one of many discrete values (such as 16 or 64 different values), which allows for very precise and individual tuning of all the memory cells in the memory array, and which makes the memory array ideal for storing and making fine tuning adjustments to the synapsis weights of the neural network.

### Neural Networks Employing Non-Volatile Memory Cell Arrays

FIG. 6 conceptually illustrates a non-limiting example of a neural network utilizing a non-volatile memory array of the present examples. This example uses the non-volatile memory array neural network for a facial recognition application, but any other appropriate application could be implemented using a non-volatile memory array based neural network.

S0 is the input layer, which for this example is a 32×32 pixel RGB image with 5 bit precision (i.e. three 32×32 pixel arrays, one for each color R, G and B, each pixel being 5 bit precision). The synapses CB1 going from input layer S0 to layer C1 apply different sets of weights in some instances and shared weights in other instances and scan the input image with 3×3 pixel overlapping filters (kernel), shifting the filter by 1 pixel (or more than 1 pixel as dictated by the model). Specifically, values for 9 pixels in a 3×3 portion of the image (i.e., referred to as a filter or kernel) are provided to the synapses CB1, where these 9 input values are multiplied by the appropriate weights and, after summing the outputs of that multiplication, a single output value is determined and provided by a first synapse of CB1 for generating a pixel of one of the feature maps of layer C1. The 3×3 filter is then shifted one pixel to the right within input layer S0 (i.e., adding the column of three pixels on the right, and dropping the column of three pixels on the left), whereby the 9 pixel values in this newly positioned filter are provided to the synapses CB1, where they are multiplied by the same weights and a second single output value is determined by the associated synapse. This process is continued until the 3×3 filter scans across the entire 32×32 pixel image of input layer S0, for all three colors and for all bits (precision values). The process is then repeated using different sets of weights to generate a different feature map of layer C1, until all the features maps of layer C1 have been calculated.

In layer C1, in the present example, there are 16 feature maps, with 30×30 pixels each. Each pixel is a new feature pixel extracted from multiplying the inputs and kernel, and therefore each feature map is a two dimensional array, and thus in this example layer C1 constitutes 16 layers of two dimensional arrays (keeping in mind that the layers and arrays referenced herein are logical relationships and may not be physical relationships—i.e., the arrays might not be oriented in physical two dimensional arrays). Each of the 16 feature maps in layer C1 is generated by one of sixteen different sets of synapse weights applied to the filter scans. The C1 feature maps could all be directed to different aspects of the same image feature, such as boundary identification. For example, the first map (generated using a first weight set, shared for all scans used to generate this first map) could identify circular edges, the second map (generated using a second weight set different from the first weight set) could identify rectangular edges, or the aspect ratio of certain features, and so on.

An activation function P1 (pooling) is applied before going from layer C1 to layer S1, which pools values from consecutive, non-overlapping 2×2 regions in each feature map. The purpose of the pooling function P1 is to average out the nearby location (or a max function can also be used), to reduce the dependence of the edge location for example and to reduce the data size before going to the next stage. At layer S1, there are 16 15×15 feature maps (i.e., sixteen different arrays of 15×15 pixels each). The synapses CB2 going from layer S1 to layer C2 scan maps in layer S1 with 4×4 filters, with a filter shift of 1 pixel. At layer C2, there are 22 12×12 feature maps. An activation function P2 (pooling) is applied before going from layer C2 to layer S2, which pools values from consecutive non-overlapping 2×2 regions in each feature map. At layer S2, there are 22 6×6 feature maps. An activation function (pooling) is applied at the synapses CB3 going from layer S2 to layer C3, where every neuron in layer C3 connects to every map in layer S2 via a respective synapse of CB3. At layer C3, there are 64 neurons. The synapses CB4 going from layer C3 to the output layer S3 fully connects C3 to S3, i.e. every neuron in layer C3 is connected to every neuron in layer S3. The output at S3 includes 10 neurons, where the highest output neuron determines the class. This output could, for example, be indicative of an identification or classification of the contents of the original image.

Each layer of synapses is implemented using an array, or a portion of an array, of non-volatile memory cells.

FIG. 7 is a block diagram of an array that can be used for that purpose. Vector-by-matrix multiplication (VMM) array 32 includes non-volatile memory cells and is utilized as the synapses (such as CB1, CB2, CB3, and CB4 in FIG. 6) between one layer and the next layer. Specifically, VMM array 32 includes an array of non-volatile memory cells 33, erase gate and word line gate decoder 34, control gate decoder 35, bit line decoder 36 and source line decoder 37, which decode the respective inputs for the non-volatile memory cell array 33. Input to VMM array 32 can be from the erase gate and wordline gate decoder 34 or from the control gate decoder 35. Source line decoder 37 in this example also decodes the output of the non-volatile memory cell array 33. Alternatively, bit line decoder 36 can decode the output of the non-volatile memory cell array 33.

Non-volatile memory cell array 33 serves two purposes. First, it stores the weights that will be used by the VMM array 32. Second, the non-volatile memory cell array 33 effectively multiplies the inputs by the weights stored in the non-volatile memory cell array 33 and adds them up per output line (source line or bit line) to produce the output, which will be the input to the next layer or input to the final layer. By performing the multiplication and addition function, the non-volatile memory cell array 33 negates the utilization of separate multiplication and addition logic circuits and is also power efficient due to its in-situ memory computation.

The output of non-volatile memory cell array 33 is supplied to a differential summer (such as a summing op-amp or a summing current mirror) 38, which sums up the outputs of the non-volatile memory cell array 33 to create a single value for that convolution. The differential summer 38 is arranged to perform summation of positive weight and negative weight.

The summed-up output values of differential summer 38 are then supplied to an activation function block 39, which rectifies the output. The activation function block 39 may provide sigmoid, tanh, or ReLU functions. The rectified output values of activation function block 39 become an element of a feature map as the next layer (e.g. C1 in FIG. 6), and are then applied to the next synapse to produce the next feature map layer or final layer. Therefore, in this example, non-volatile memory cell array 33 constitutes a plurality of synapses (which receive their inputs from the prior layer of neurons or from an input layer such as an image database), and summing op-amp 38 and activation function block 39 constitute a plurality of neurons.

The input to VMM array 32 in FIG. 7 (WLx, EGx, CGx, and optionally BLx and SLx) can be analog level, binary level, or digital bits (in which case a DAC is provided to convert digital bits to appropriate input analog level) and the output can be analog level, binary level, or digital bits (in which case an output ADC is provided to convert output analog level into digital bits).

FIG. 8 is a block diagram depicting the usage of numerous layers of VMM arrays 32, here labeled as VMM arrays 32a, 32b, 32c, 32d, and 32e. As shown in FIG. 8, the input, denoted Inputx, is converted from digital to analog by a digital-to-analog converter 31 and provided to input VMM array 32a. The converted analog inputs could be voltage or current. The input D/A conversion for the first layer could be done by using a function or a LUT (look up table) that maps the inputs Inputx to appropriate analog levels for the matrix multiplier of input VMM array 32a. The input conversion could also be done by an analog to analog (A/A) converter to convert an external analog input to a mapped analog input to the input VMM array 32a.

The output generated by input VMM array 32a is provided as an input to the next VMM array (hidden level 1) 32b, which in turn generates an output that is provided as an input to the next VMM array (hidden level 2) 32c, and so on. The various layers of VMM array 32 function as different layers of synapses and neurons of a convolutional neural network (CNN). Each VMM array 32a, 32b, 32c, 32d, and 32e can be a stand-alone, physical non-volatile memory array, or multiple VMM arrays could utilize different portions of the same physical non-volatile memory array, or multiple VMM arrays could utilize overlapping portions of the same physical non-volatile memory array. The example shown in FIG. 8 contains five layers (32a,32b,32c,32d,32c): one input layer (32a), two hidden layers (32b,32c), and two fully connected layers (32d,32c). One of ordinary skill in the art will appreciate that this is merely an example and that a system instead could comprise more than two hidden layers and more than two fully connected layers.

Each non-volatile memory cell used in a neural network is to be erased and programmed to hold a very specific and precise amount of charge, i.e., the number of electrons, in the floating gate. For example, each floating gate is to hold one of N different values, where N is the number of different weights that can be indicated by each cell. Examples of N include 16, 32, 64, 128, and 256.

One challenge of implementing a neural network using analog memory cells is that extreme precision is required for erase, program, and read operations of each cell, as each floating gate in each cell may be required to hold one of N values, where N is greater than the conventional value of 2 used in conventional flash memory systems. However, the characteristics of each device, such as its current-voltage response characteristic curve, will change as its operating temperature changes. The current drawn by a memory cell when operating in the sub-threshold region changes exponentially as temperature changes.

Applicant previously proposed a mechanism for temperature compensation in U.S. Pat. No. 10,755,783, titled, “Temperature and Leakage Compensation for Memory Cells in an Analog Neural Memory System Used in a Deep Learning Neural Network,” which is incorporated by reference. That mechanism applied temperature compensation separately and sequentially to erase gate terminals and control gate terminals of non-volatile memory cells. This utilized significant die space for the circuitry to control both terminals as well as significant time since the erase gate terminals and control gate terminals were handled in a sequential manner.

What is needed is a system for providing temperature compensation for analog memory cells in a neural network to maintain approximately constant array current as temperature changes in a way that uses less die space and less time than prior art mechanisms.

### SUMMARY OF THE INVENTION

Numerous examples are disclosed for providing temperature compensation for analog memory cells used in a neural network.

In one example, a method comprises determining a bias voltage in response to a change in operating temperature of an array of non-volatile memory cells, each of the non-volatile memory cells in the array of memory cells comprising a control gate terminal and an erase gate terminal; and applying the bias voltage to a control gate terminal and an erase gate terminal of a selected memory cell in the array of memory cells while reading the selected memory cell.

In another example, a circuit to generate a control gate and erase gate bias voltage comprises a reference memory cell comprising a control gate terminal, an erase gate terminal, and a bit line terminal; a current digital-to-analog converter to generate a current in response to a digital input and to apply the current to the bit line terminal; and an operational amplifier comprising an inverting terminal coupled to a bit line, a non-inverting terminal coupled to a reference voltage, and an output terminal providing a voltage to the control gate terminal and the erase gate terminal, wherein the voltage is output from the circuit as the control gate and erase gate bias voltage.

In another example, a method comprises determining a bias voltage in response to a change in operating temperature of an array of non-volatile memory cells, each of the non-volatile memory cells in the array of memory cells comprising a control gate terminal and an erase gate terminal; and applying voltages based on the bias voltage to a control gate terminal and an erase gate terminal of a selected memory cell in the array of memory cells while reading the selected memory cell.

In another example, a method comprises conducting a bias current through a reference memory cell; generating a bias voltage based on the bias current; and applying the bias voltage to a control gate terminal and an erase gate terminal of a selected memory cell during a read operation.

In another example, a method comprises deriving a bias voltage from a combined control gate and erase gate temperature compensated voltage; and providing the bias voltage to control gate terminals and erase gate terminals of selected memory cells during a read operation.

In another example, a system comprises an array of non-volatile memory cells arranged into rows and columns, each of the non-volatile memory cells comprising a control gate terminal and an erase gate terminal, wherein the control gate terminal of each non-volatile memory cell in a row is coupled to a control gate line and the erase gate terminal of each non-volatile memory cell in a row is coupled to an erase gate line; and a plurality of row circuits, each row circuit applying a voltage to a control gate line and an erase gate line coupled to a row of the array during a read operation of one or more non-volatile memory cells in the row.

### BRIEF DESCRIPTION OF THE DRAWINGS

FIG. 1 is a diagram that illustrates a prior art artificial neural network.

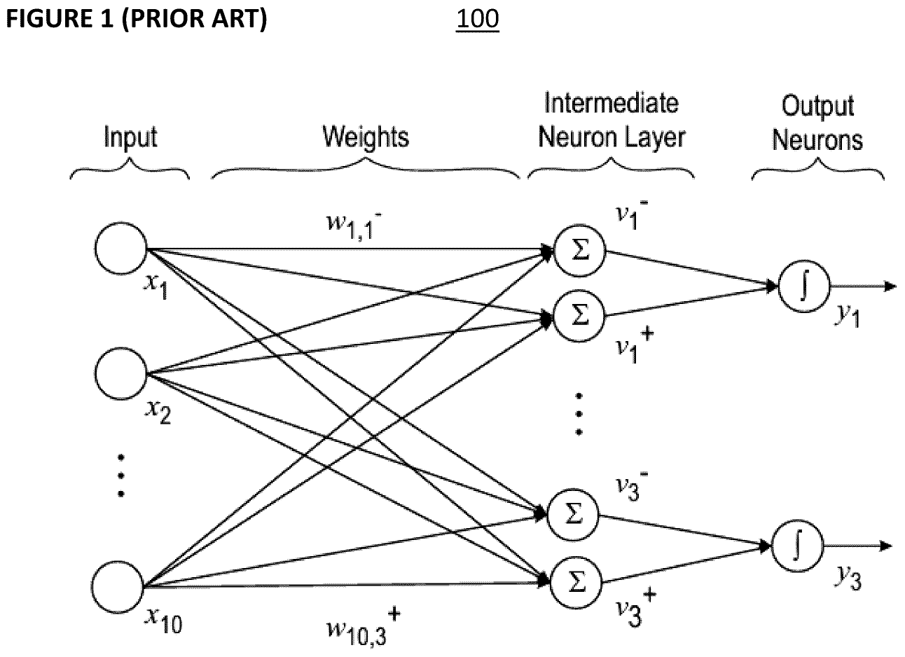

FIG. 2 is a cross-sectional side view of a conventional 2-gate non-volatile memory cell.

FIG. 3 is a cross-sectional side view of a conventional 4-gate non-volatile memory cell.

FIG. 4 is a side cross-sectional side view of conventional 3-gate non-volatile memory cell.

FIG. 5 is a cross-sectional side view of another conventional 2-gate non-volatile memory cell.

FIG. 6 is a diagram illustrating the different levels of an example artificial neural network utilizing a non-volatile memory array.

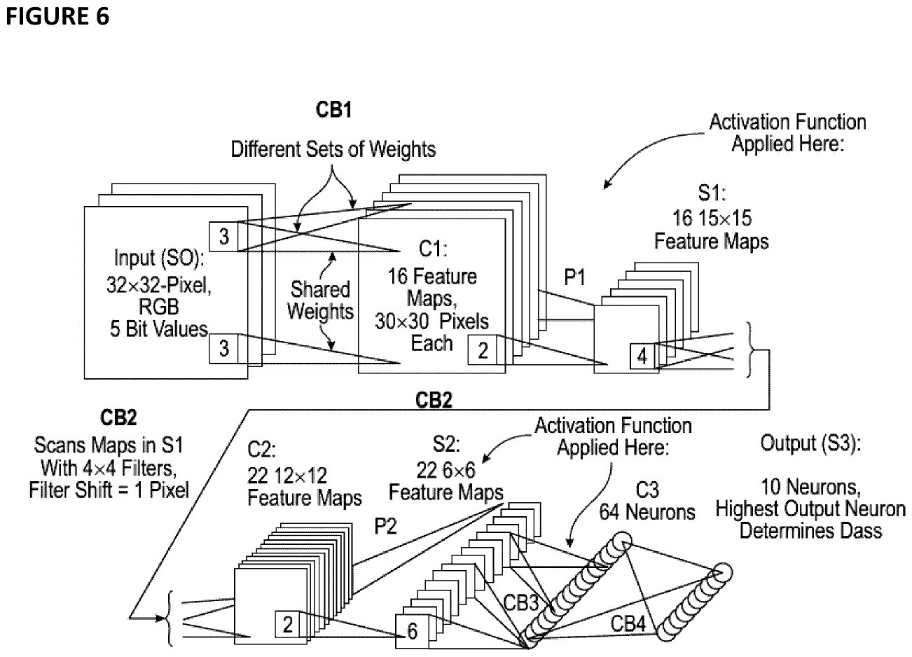

FIG. 7 is a block diagram illustrating a vector multiplier matrix.

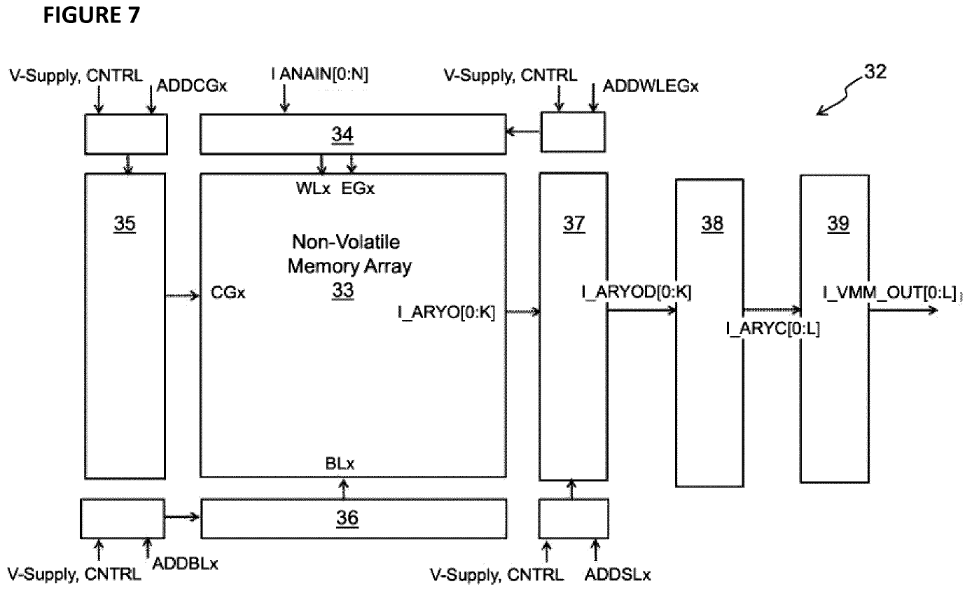

FIG. 8 is a block diagram illustrating various levels of a vector multiplier matrix.

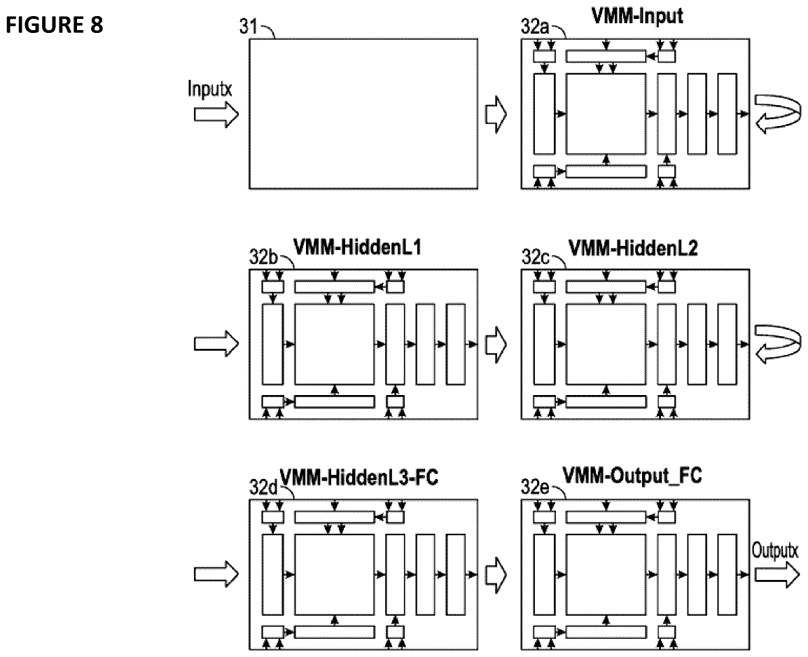

FIG. 9 is a block diagram of a VMM system.

FIG. 10 depicts an input circuit for a VMM system.

FIG. 11 depicts a circuit for generating voltages to apply to erase gate and control terminals of non-volatile memory cells in a VMM system.

FIG. 12 depicts an output circuit for a VMM system.

FIG. 13 depicts a circuit for generating a bias voltage to apply to a control gate and erase gate of a non-volatile memory cell to compensate for a change in temperature.

FIG. 14 depicts a row driver for a control gate line and erase gate line of a row of non-volatile memory cells.

FIG. 15 depicts an input circuit for a VMM system.

FIG. 16 depicts an input circuit for a VMM system.

FIG. 17 depicts a method of compensating for changes in temperature.

FIG. 18 depicts a method of compensating for changes in temperature.

FIG. 19 depicts a change in read current of a non-volatile memory cell in response to a change in temperature and the resulting change in voltage on an erase gate terminal of the cell.

FIG. 20 depicts a change in read current of a non-volatile memory cell in response to a change in temperature and the resulting change in voltage on an erase gate terminal of the cell.

FIG. 21 depicts a change in read current of a non-volatile memory cell in response to a change in temperature and the resulting change in voltage on an erase gate terminal of the cell.

### DETAILED DESCRIPTION OF THE INVENTION

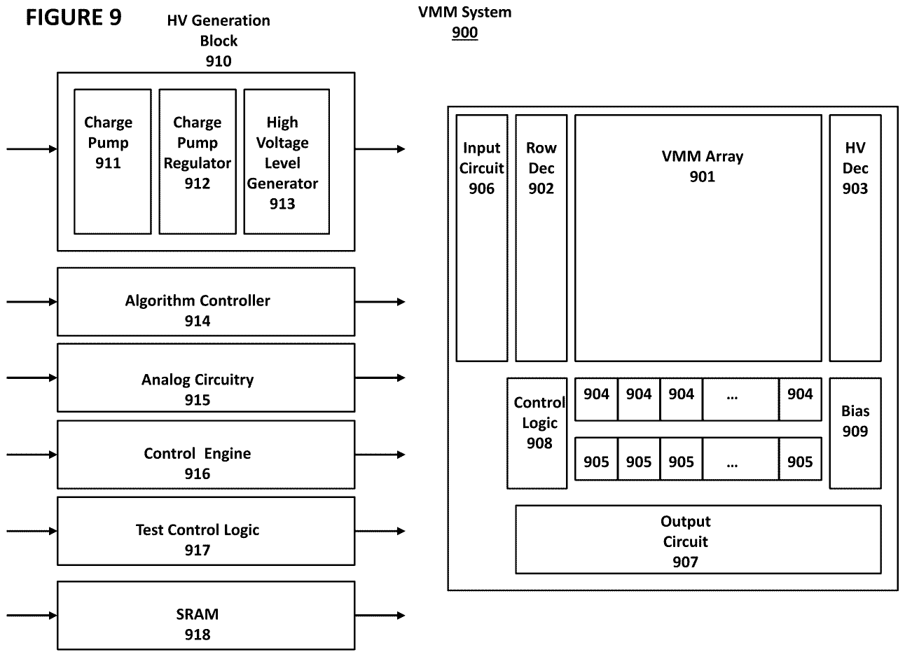

FIG. 9 depicts a block diagram of VMM system 900. VMM system 900 comprises VMM array 901, row decoder 902, high voltage decoder 903, column decoders 904, bit line drivers 905 (such as bit line control circuitry for programming), input circuit 906, output circuit 907, control logic 908, and bias generator 909. VMM system 900 further comprises high voltage generation block 910, which comprises charge pump 911, charge pump regulator 912, and high voltage level generator 913. VMM system 900 further comprises (program/erase, or weight tuning) algorithm controller 914, analog circuitry 915, control engine 916 (that may include functions such as arithmetic functions, activation functions, embedded microcontroller logic, without limitation), test control logic 917, and static random access memory (SRAM) block 918 to store intermediate data such as for input circuits (e.g., activation data) or output circuits (neuron output data, partial sum output neuron data) or data in for programming (such as data in for a whole row or for multiple rows).

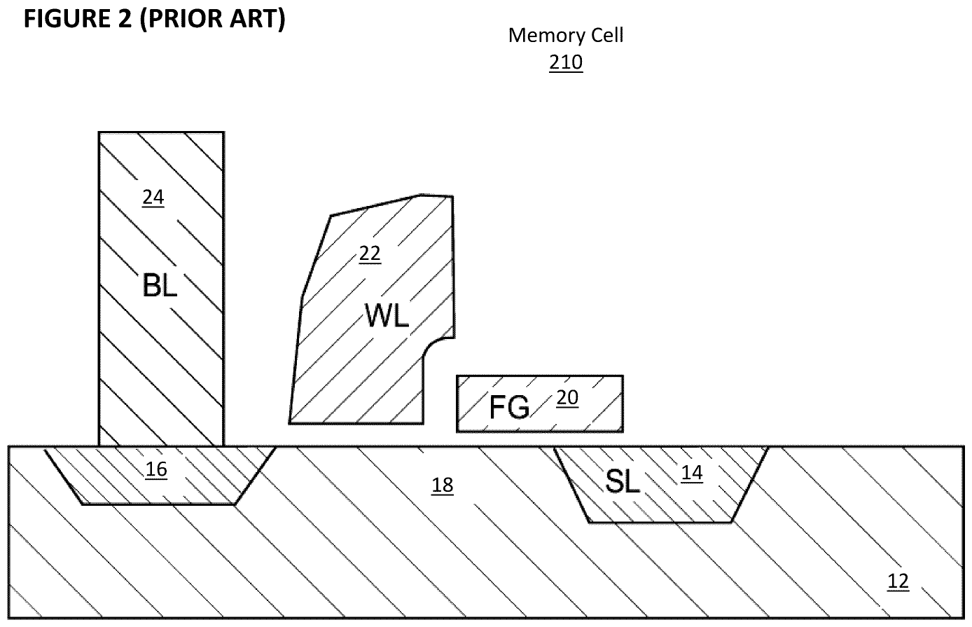

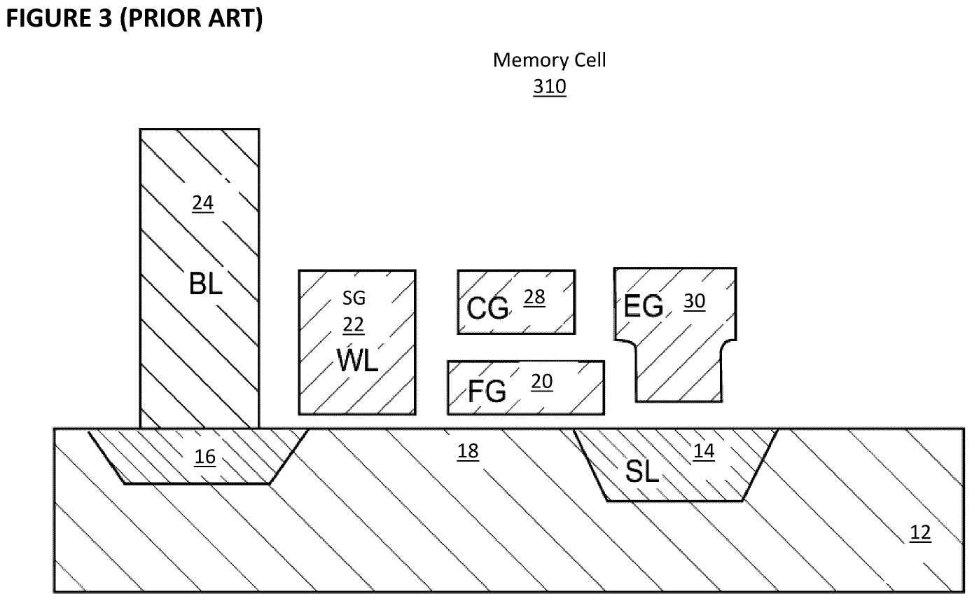

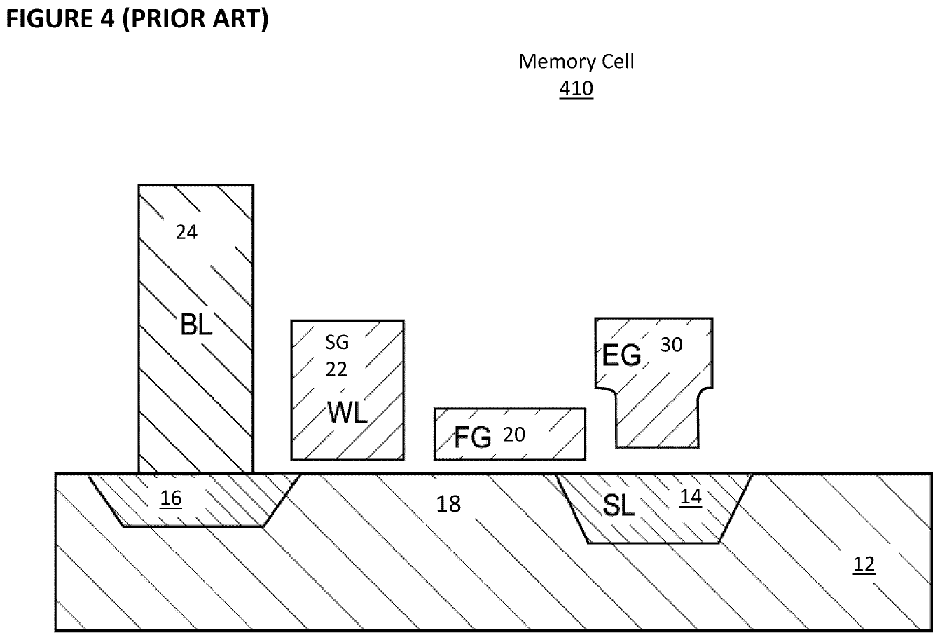

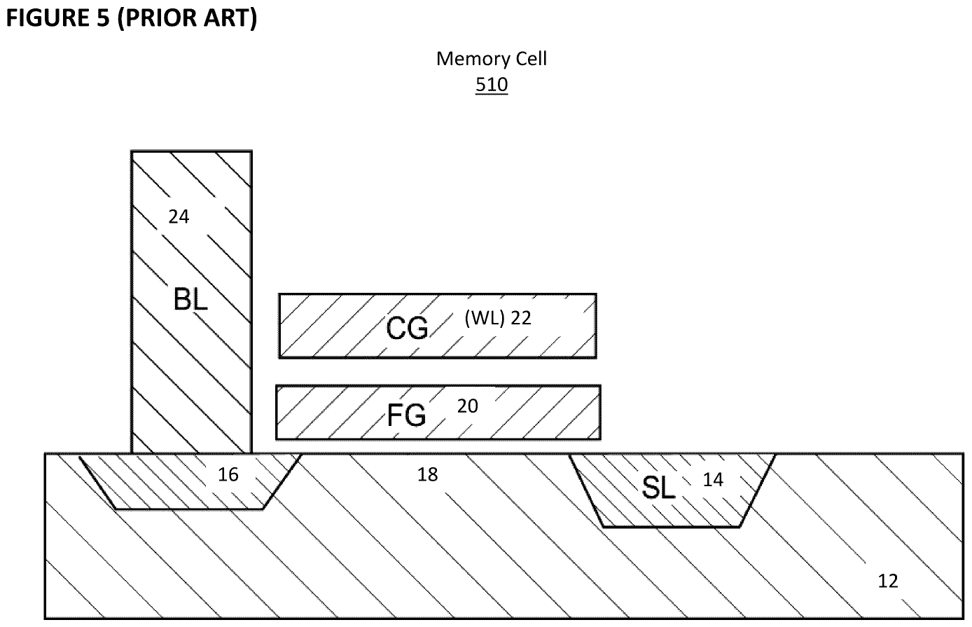

VMM array 901 comprises an array of non-volatile memory cells arranges in rows and columns. In one example, the memory cells of VMM array 901 comprise split-gate flash memory cells such as cells based on the design of memory cell 210, 310, or 410 in FIGS. 2, 3, and 4, respectively. In another example, the memory cells of VMM array 901 comprise stacked-gate flash memory cells such as cells based on the design of memory cell 510 in FIG. 5.

The input circuit 906 may include circuits such as a DAC (digital to analog converter), DPC (digital to pulses converter, digital to time modulated pulse converter), AAC (analog to analog converter, such as a current to voltage converter, logarithmic converter), PAC (pulse to analog level converter), or any other type of converters. The input circuit 906 may implement one or more of normalization, linear or non-linear up/down scaling functions, or arithmetic functions. The input circuit 906 may implement a temperature compensation function for input levels. The input circuit 906 may implement an activation function such as ReLU or sigmoid. Input circuit 906 may store digital activation data to be applied as, or combined with, an input signal during a program or read operation. The digital activation data can be stored in registers. Input circuit 906 may comprise circuits to drive the array terminals, such as CG, WL, EG, and SL lines, which may include sample-and-hold circuits and buffers. A DAC can be used to convert digital activation data into an analog input voltage to be applied to the array.

The output circuit 907 may include circuits such as an ITV (current-to-voltage circuit), ADC (analog to digital converter, to convert neuron analog output to digital bits), AAC (analog to analog converter, such as a current to voltage converter, logarithmic converter), APC (analog to pulse(s) converter, analog to time modulated pulse converter), or any other type of converters. The output circuit 907 may convert array outputs into activation data. The output circuit 907 may implement an activation function such as rectified linear activation function (ReLU) or sigmoid. The output circuit 907 may implement one or more of statistic normalization, regularization, up/down scaling/gain functions, statistical rounding, or arithmetic functions (e.g., add, subtract, divide, multiply, shift, log) for neuron outputs. The output circuit 907 may implement a temperature compensation function for neuron outputs or array outputs (such as bitline output) so as to keep power consumption of the array approximately constant or to improve precision of the array (neuron) outputs such as by keeping the IV slope approximately the same over temperature. The output circuit 907 may comprise registers for storing output data.

In the examples discussed below, parameters of input circuit 906 and output circuit 907 may be configured depending on the type of neural network being implemented (for example, an MLP, CNN, RNN, or other type of network), the nature of the layer being implemented (for example, the first layer, a middle layer, or the last layer), on neural CNN operation being performed (for example, depthwise, 1D, or 2D), on the filter size or kernel size (for example, 3×3, 1×1, 7×7, or other size), on the channel depth (for example, 32, 64, 128, or another size).

Within output circuit 907, ITVs can be configured per network layer to receive different input ranges and produce a constant array output which is used by the ADC to produce, for example, an 8-bit output. A resistor-based ITV (R-ITV) can be adjusted by changing one or more resistor values. A capacitor-based ITV (C-ITV) can be adjusted by changing one or more capacitor values or the integration time. ADCs can be configured per network layer to receive different input ranges from the ITV and produce a constant resolution such as an 8-bit output, A current mirror also can be used to mirror the array output with an adjustable ratio, Adjusting ITVs, ADCs, and current mirrors make it possible to implement a wide range of VMM outputs.

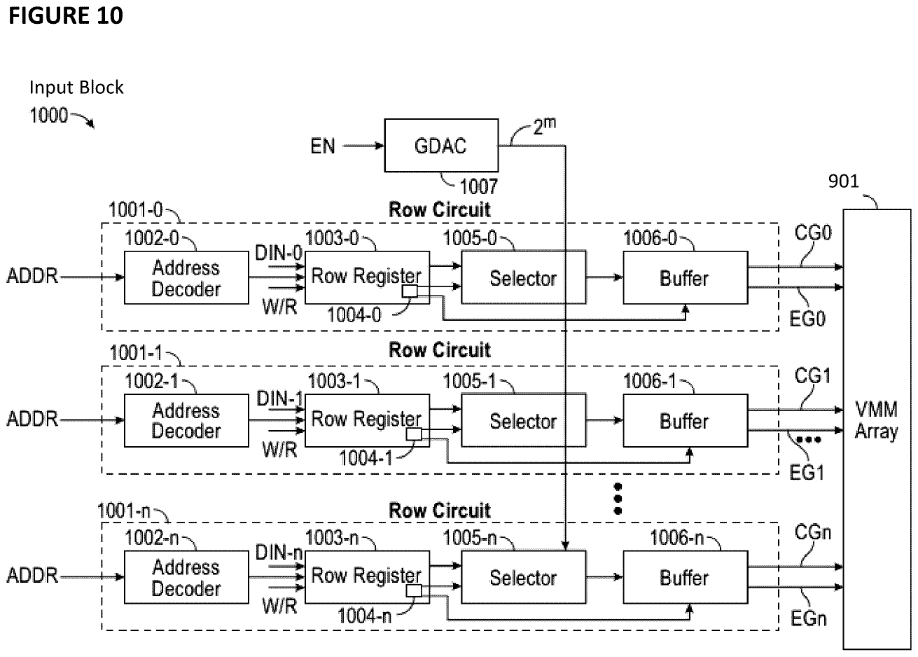

FIG. 10 depicts an example of components that can be used in input circuit 906 of FIG. 9 for purposes of applying input values to rows of VMM array 901 as well as a bias voltage to control gate terminals and erase gate terminals of the rows during a read operation, where the input values will be multiplied by weights stored in cells of VMM array 901 and each column of VMM array 901 will generate an output current representing a sum of the products of each cell in the column multiplied by the input value received by that cell.

FIG. 10 depicts input block 1000. Input block 1000 comprises row circuits 1001-0, 1001-1, . . . , 1001-n for rows 0 to n, and global digital-to-analog converter (GDAC) 1007. VMM array 901 is shown for clarity, but VMM array 901 is not part of input block 1000. Input block 1000 is an example implementation of input circuit 906 in FIG. 9.

Row circuit 1001-0 is an input circuit that generates, and applies, output CG0 and EG0 to the control gate line and erase gate line, respectively, of row 0 of non-volatile memory cells in VMM array 901; row circuit 1001-1 is an input circuit that generates, and applies, output CG1 and EGI to the control gate line and erase gate line, respectively of row 1 of non-volatile memory cells in VMM array 901; row circuit 1001-n is an input circuit that generates, and applies, output CGn and EGn to the control gate line and erase gate line, respectively, of row n of non-volatile memory cells in VMM array 901; and all other row circuits 1001 have the same role as to an associated row in VMM array 901.

Row circuit 1001-0 comprises address decoder 1002-0, row register 1003-0, tag bit 1004-0, selector 1005-0, and buffer 1006-0. Similarly, row circuit 1001-1 comprises address decoder 1002-1, row register 1003-1, tag bit 1004-1, selector 1005-1, and buffer 1006-1; row circuit 1001-n comprises address decoder 1002-n, row register 1003-n, tag bit 1004-n, selector 1005-n, and buffer 1006-n; and all other row circuits 1001 have the same structure.

Each row circuit 1001 operates in the same manner. The load and read operations will be described as to row circuit 1001-0 but it is to be understood that this explanation applies to all other row circuits 1001 as well.

During a load operation, the W/R port on row register 1003-0 receives a value indicating a write operation (e.g., “0”) and row register 1003-0 is loaded with input data comprising m bits of data. For example, m might be 8, 16, 32, 64, 128, 256, or another other number. The input data to be loaded can be activation data or input data such as from an object or image that is to be classified or recognized by a neural network application. Address decoder 1002-0 receives an address, ADDR. If ADDR matches the address associated with row 0, address decoder 1002-0 asserts its output signal, which is provided to row register 1003-0. Row register 1003-0, in response to the asserted output signal of address decoder 1002-0, performs a load operation and stores the received data-in, DIN-0. The loaded data is used in a subsequent read or verify operation.

Row register 1003-0 also stores tag bit 1004-0, which tag bit 1004-0 can be used to enable or disable row 0, such as by disabling the output of selector 1005-0 or buffer 1006-0, regardless of whether the row is selected or not selected by address decoder 1002. For example, if tag bit 1004-0 has a certain value (e.g., “1”), the activation data in row register 1003-0 will be output when ADDR indicates that row 0 is selected. If tag bit 1004-0 has a different value (e.g., “0”), the activation data in row register 1003-0 will not be output because, for example, the tag bit value will disable the output of row register 1003-0, selector 1005-0 (for example, by serving as an input to an enable port), or buffer 1006-0 (for example, by serving as an input to an enable port), and a default value (e.g., “0”) will instead be output even when ADDR indicates that row 0 is selected. Tag bits 1004 can be useful, for example, to save power when a controller (not shown) determines that a read operation can be skipped. When row register 1003-0 is not disabled by tag bit 1004-0, it will output the data that was stored in it during the load operation when address decoder 1002-2 asserts its output in response to receiving the address ADDR that corresponds to row 0.

During a read or verify operation, address decoder 1002-0 receives an address, ADDR. If ADDR matches the address associated with row 0, address decoder 1002-0 asserts its output signal, which is provided to row register 1003-0. The W/R port on row register 1003-0 receives a value indicating a read operation (e.g., “1”) and row register 1003-0, in response to the asserted output signal of address decoder 1002-0, outputs its stored data, DIN-0 if its tag bit 1004-0 is a value (e.g., “1”) that enables the output of data.

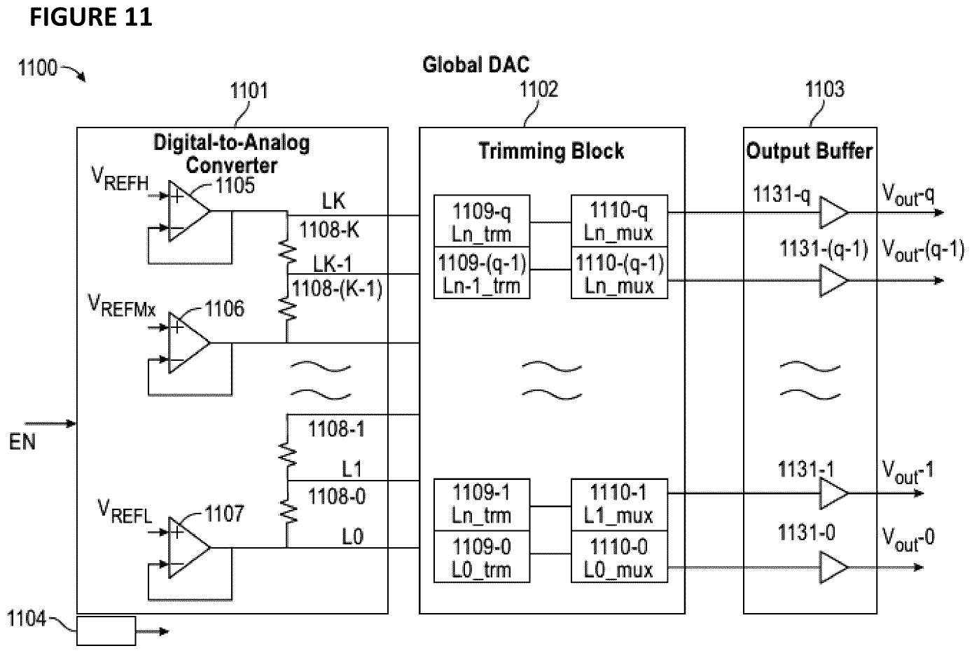

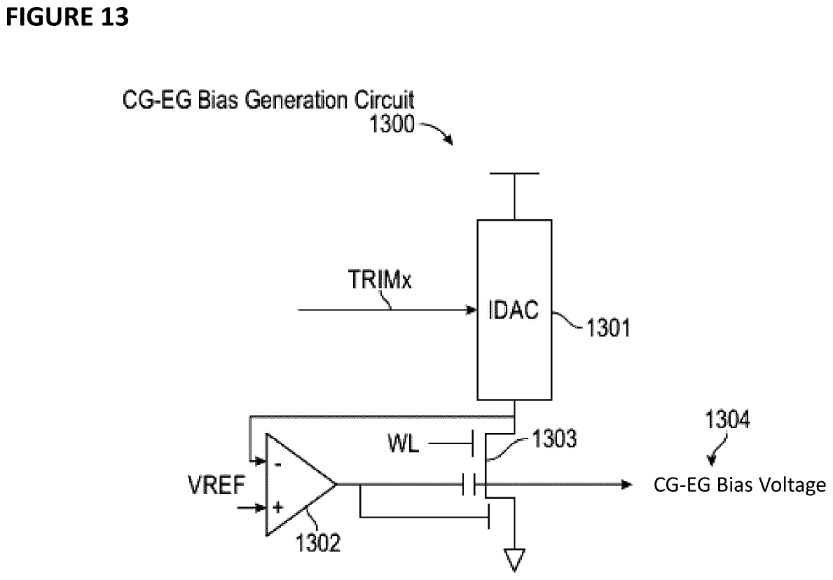

GDAC 1007 receives an enable signal, EN, and when enabled, outputs 2^{m} different analog voltages on 2^{m} different output lines, where the 2^{m} different analog voltages represent the set of possible analog voltages that can be applied to a control gate line in VMM array 901. Notably, the 2^{m} different analog voltages generated by GDAC 1007 are compensated for a change in temperature through the reference voltages that are supplied to the GDAC 1007 (e.g., VREFH, VREFMx, VREFL in FIG. 11, which are generated based on a reference voltage such as CG-EG bias voltage 1304 in FIG. 13). Selector 1005 receives a value from row register 1003-0 (which can be “0” if ADDR is not the address corresponding to row 0, if tag bit 1004-0 was a value that does not enable the output of data, or if the stored activation data in row register 1003-0 is “0”; and which otherwise will be the value stored in row register 1003-0). Selector 1005-0 receives all 2m lines from GDAC 1007 and selects a particular line based on the m bit value received from row register 1003-0. The analog voltage from the selected line from GDAC 1007 is then provided to buffer 1006-0, which will then provide a buffered version of the received analog voltage (i.e., the buffered version of the received analog voltage will not substantially vary based on the input impedance or capacitance of VMM array 901) to the control gate line CG0 and erase gate line EG0 of VMM array 901.

FIG. 11 depicts global digital-to-analog converter 1100, which can be used as GDAC 1007 in FIG. 10. Global digital-to-analog converter 1100 comprises digital-to-analog converter (DAC) 1101, trimming block 1102, and output buffer 1103. Control logic 1104 controls the operation of global digital-to-analog converter 1100, such as by enabling various blocks using enable signals (e.g., EN), providing control signals to multiplexors, and generating other control signals.

DAC 1101 receives a high reference voltage (VREFH), a medium reference voltage (VREFMx), and a low reference voltage, VREFL, provided to voltage buffers 1105, 1106, and 1107, respectively. Reference voltages VREFH/VREFM/VREFL are generated by a reference circuit that is based on the combined CG+EG compensated reference voltage such as CG+EG BIAS in FIG. 13. The values of reference voltages VREFH, VREFM, VREFL are determined in response to the maximum current level, medium current level, and low current level corresponding to the operation cell current range of VMM array 901, for example, from 0-100 nA. Additional other reference voltages can be used, such as reference voltages with values between VREFL and VREFM and between VREFM and VREFH.

DAC 1101 comprises a voltage ladder comprising a plurality of resistors 1108-0, 1108-1, . . . , 1108-(k−1), 1108-k that are used to generate a range of voltages (L0, L1, . . . , L(k−1), Lk) between VREFH and VREFMx and between VREFMx and VREFL, optionally according to a linear function, a logarithmic function or a customized logarithmic function (e.g., where the memory cell operates in the sub-threshold region). For example, the top node of the top resistor 1108-k in the voltage ladder will have a voltage Lk equal to VREFH, and the bottom node of the bottom resistor 1108-0 in the voltage ladder will have a voltage L0 equal to VREFL, with intermediate nodes having voltages between VREFH and VREFL based on the voltage drop across resistors above and below the node. The voltage ladder thereby generates a plurality of voltage levels (L0, . . . , Lk) (for example, k might be 4095), which are used when it is desired to provide a voltage to a VMM array to cause the non-volatile memory cells of the VMM array to operate in linear mode or sub-threshold mode. VREFM can be chosen so that DAC 1101 simulates cell behavior.

Trimming block 1102 receives q+1 voltages from digital-to-analog converter. Trimming block 1102 comprises sub blocks 1109-0, 1109-1, . . . , 1109-(q−1), 1109-q and multiplexors 1110-0, 1110-1, . . . , 1110-(q−1), and 1110-q. Thus, trimming block 1102 comprises (q+1) trim blocks 1109 and (q+1) multiplexors 1110. Trimming block 1102 performs local trimming on each of the q+1 voltage levels. This may be useful, for example, when the non-volatile memory cells in the array are operating in the sub-threshold region. This is desirable to achieve a good matching I-V slope for the non-volatile memory cells in the VMM array over temperature in sub threshold region or linear region.

By adjusting reference voltages VREFL, VREFM, and VREFH, the k+1 levels are adjusted as well. This is, for example, to match the output range of this input block with an input range of the memory cells. The reference levels VREFL, VREFM, and VREFH change in response to changes of temperature since they are based on the combined CG+EG compensated reference voltage such CG+EG BIAS in FIG. 13. Further individual voltage level adjustment and temperature compensation can be performed by trimming circuits of trimming block 1102.

The output from multiplexors 1110 is provided to output buffer 1103, which provides output voltages VOUT-0 to VOUT-q, where (q+1)=2^{m} in FIG. 10. For example, if m=4, (q+1)=16, meaning that global DAC 1100 will generate 16 different voltage outputs. Output buffer 1103 comprises buffers 1131-0, 1131-1, . . . , 1131-(q−1), 1131-q.

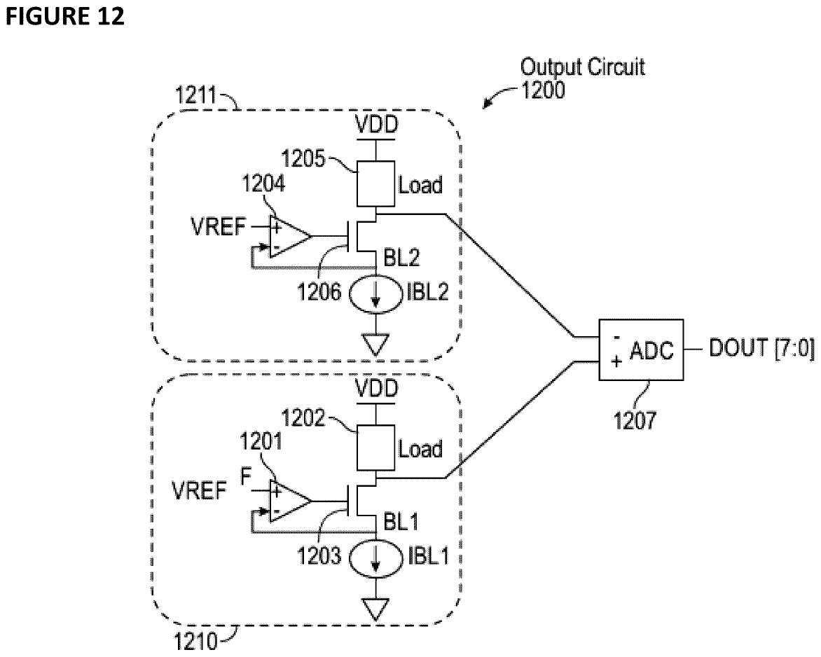

FIG. 12 depicts output circuit 1200, which can be used for two columns in output circuit 907 in FIG. 9. Output circuit 1200 is used to read a value stored in differential memory cells coupled to a first bit line and a second bit line in an array of memory cells, where IBL1 is the current drawn by the first bit line coupled to a first column of cells in the array and IBL2 is the current drawn by the second bit line coupled to a second column of cells in the array and generate differential digital output bits by a differential ADC.

Read circuit 1200 comprises current-to-voltage converter 1210 (a first current-to-voltage converter), current-to-voltage converter 1211 (a second current-to-voltage converter), and differential ADC 1207 (which can be a SAR ADC or other type of ADC).

Current-to-voltage converter 1210 comprises operational amplifier 1201 (a first operational amplifier) (or an equivalent regulating circuit), load 1202 (a first load, which can comprise one or more resistors, capacitors, or transistors), and NMOS transistors 1203 (a first transistor). Load 1202 comprises a first terminal coupled to a voltage source VDD and a second terminal. NMOS transistor 1203 comprises a first terminal coupled to the second terminal of load 1202, a gate, and a second terminal coupled to the first bit line. Operational amplifier 1201 comprises an inverting input coupled to the first bit line, an inverting input coupled to VREF1 (a first reference voltage) and an output coupled to the gate of NMOS transistor 1203.

Current-to-voltage converter 1211 comprises operational amplifier 1204 (a second operation amplifier) (or an equivalent regulating circuit), load 1205 (a second load, which can comprise one or more resistors, capacitors, or transistors), and NMOS transistor 1206 (a second transistor). Load 1205 comprises a first terminal coupled to a voltage source VDD and a second terminal. NMOS transistor 1206 comprises a first terminal coupled to the second terminal of load 1205, a gate, and a second terminal coupled to the second bit line. Operational amplifier 1204 comprises an inverting input coupled to the second bit line, an inverting input coupled to VREF2 (a second reference voltage, which can be the same or different than VREF1) and an output coupled to the gate of NMOS transistor 1203.

As an example, using a 12.5 kΩ resistor for loads 1202 and 1205 will generate currents of approximately 25 uA into the terminals of NMOS transistors 1203 and 1206, respectively.

ADC 1207 comprises a first input coupled to the second terminal of the first load, a second input coupled to the second terminal of the second load, and an output to generate a set of output bits.

Thus, the non-inverting inputs of operational amplifiers 1201 and 1204 are each coupled to a reference voltage Vref, and the source of regulating transistors 1206 and 1203 are connected to the inverting input of operational amplifiers 1204 and 1201, respectively. The source voltage of transistors 1206 and 1203 are thus driven to be equal to VREF, meaning voltages of BL1 and BL2 coupled to the selected cells are driven to VREF voltage). Here, the voltages provided to the inverting and non-inverting terminals of ADC 1207 are referenced with respect to the supply voltage, VDD, and are the result of voltage drops from the supply voltage in amounts equal to the currents IBL2 and IBL1 through loads 1205 and 1202, respectively. The output of the ADC effectively implements W=W+−W−.

FIG. 13 depicts CG-EG bias generation circuit 1300, which comprises current digital-to-analog converter 1301, operational amplifier 1302, and reference memory cell 1303. Reference memory cell 1303 is the same type of memory cell used in VMM array 901. Current digital-to-analog converter 1301 generates an analog current in response to a digital input, TRIMx. The analog current is applied to the bit line terminal of reference memory cell 1303, which is coupled to the inverting terminal of operational amplifier 1302. The non-inverting terminal of operational amplifier 1302 receives a reference voltage, VREF. The output of operational amplifier 1302 is applied to the control gate terminal and erase gate terminal of reference memory cell 1303 and is output as CG-EG bias voltage 1304, which can be used for the reference voltage discussed previously for FIG. 11. As the operating temperature of VMM array 901 changes, the operating temperature of reference memory cell 1303 also will change. As the operating temperature of reference memory cell 1303 changes, its ability to draw from current digital-to-analog converter 1301 will change, resulting in a change in the voltage CG-EG bias to keep it constant. Applying CG-EG bias voltage 1304 to the control gate and erase gate terminals of selected memory cells (such as by using it for the reference voltage discussed previously for FIG. 11) during read operations provides temperature compensation to those selected memory cells such that their read current will remain approximately constant for a given input as their operating temperature changes.

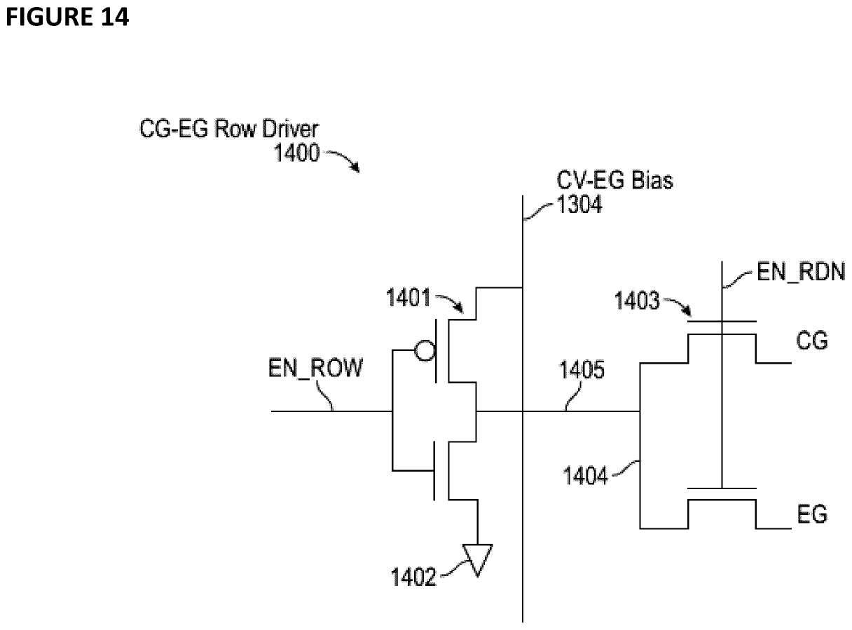

FIG. 14 depicts CG-EG row driver 1400, which is another mechanism by which CG-EG bias voltage 1304 can be provided to the control gate and erase gate terminals of a row of memory cells. CG-EG row driver 1400 comprises PMOS transistor 1401, NMOS transistor 1402, NMOS transistor 1403, and NMOS transistor 1404 coupled as shown. CG-EG row driver 1400 is coupled to an associated row of non-volatile memory cells in VMM array 901. Instantiations of CG-EG row driver 1400 will be present for all rows of VMM array 901. PMOS transistor 1401 and NMOS transistor 1402 receive a control signal, EN_ROW, which signifies whether the associated row is enabled for an operation. When EN_ROW is low, the row is enabled, and PMOS transistor 1401 will be turned and will pull node 1405 to CG-EG bias voltage 1304. When EN_ROW is high, the row is not enabled, and NMOS transistor 1402 will be turned on and will pull node 1405 down to ground. Control signal EN_RDN is high when the associated row is enabled specifically for a read operation. When EN_RDN is high, NMOS transistors 1403 and 1404 will be turned on and will provide the voltage of node 1405 to the control gate line, CG, and the erase gate line, EG, respectively, of the associated row. CG-EG row driver 1400 provides the same bias voltage to the CG and EG terminals of selected memory cells when the row driver is selected by a row decoder (not shown). CG-EG row driver 1400 provides the ground voltage to the CG and EG terminals of selected memory cells when the row driver is de-selected by a row decoder (not shown). In one example using CG-EG row driver 1400, the input activation also can be applied to the cell by applying the single bit at a time in serial fashion, where the output is accumulated, shifted, and added for a multi-bit activation input. In another example using CG-EG row driver 1400, the input activation can be applied to the cell by pulsing the application of CG-EG bias voltage 1304 to the control gate and erase gate terminals, for example, by altering the width of the pulse or the number of pulses based on the value of the activation input.

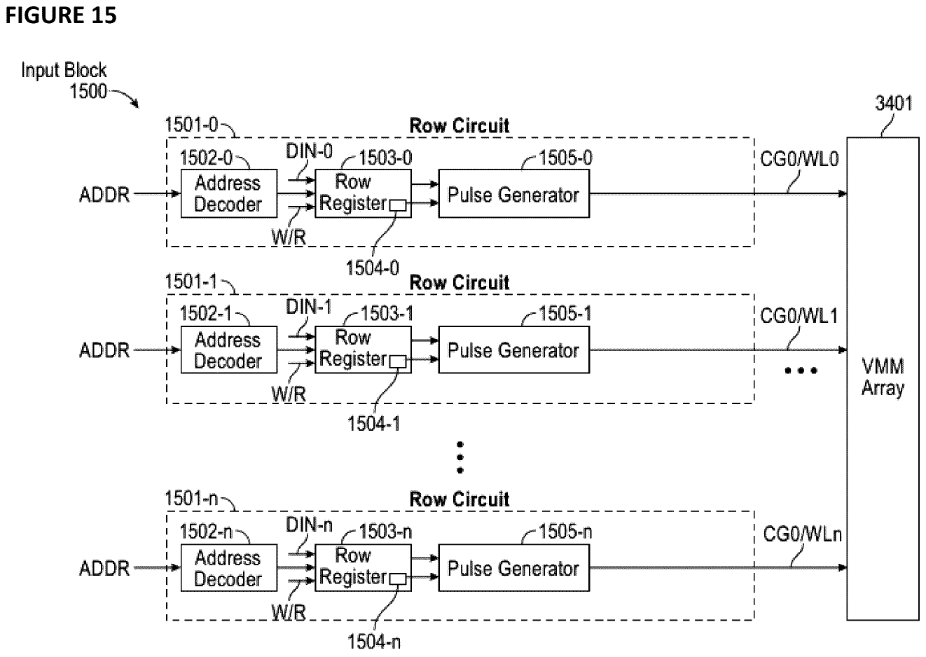

The latter example is shown in FIG. 15. FIG. 15 depicts input block 1500. Input block 1500 comprises row circuits 1501-0, 1501-1, . . . , 1501-n. Row circuits 1501 each comprise address decoder 1502 and row register 1503, which perform the same functions as address decoder 1002 and row register 1003, respectively, in FIG. 10. Row circuits 1501 also comprise pulse generator 1505-0, 1505-1, . . . , 1505-n, which can generate a pulse with peak voltage CG-EG bias voltage 1304 (not shown) where the width varies in response to the activation data in row register 1503 or which can generate a series of pulses with peak voltage CG-EG bias voltage 1304 where the number of pulses varies in response to the activation data in row register 1503. This can be performed for the entirety of an input or in a bit-by-bit serial fashion with same pulse width for each bit operation. Alternatively, the pulse generator can generate the pulse on the word line terminals instead on the CG and EG terminals. In this case, the CG and EG terminals of the array are biased at a bias voltage that is compensated over temperature such as from CG+EG BIAS 1304 in FIG. 13.

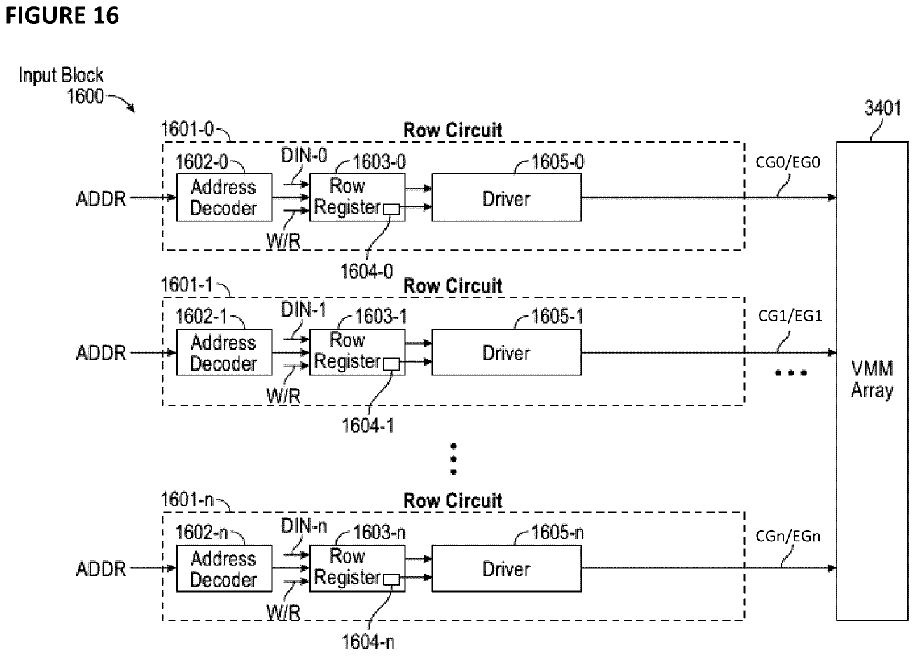

FIG. 16 depicts input block 1600 which is similar to input block 1500 of FIG. 15 except the pulse generator 1505 in FIG. 15 is replaced by driver 1605. Driver 1605 provides a bias voltage, such as CG+EG BIAS 1304 from FIG. 13, on the CG and EG lines of the associated row. Driver 1605 comprises, for example, an inverter, a buffer, or one or more logic gates. Each input block 1601 can operate on a bit-by-bit serial input fashion in which each input bit of an activation is operated at a time in read operation. The operational results for the inputs in the read operation are shifted and added per the binary position of the input bits.

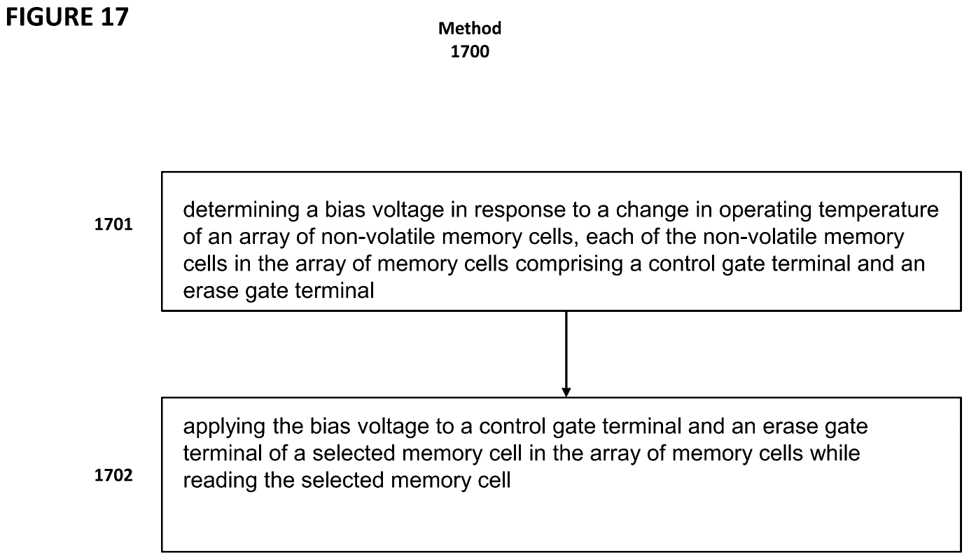

FIG. 17 depicts a method 1700 of compensating for changes in temperature. The method comprises determining a bias voltage in response to a change in operating temperature of an array of non-volatile memory cells, each of the non-volatile memory cells in the array of memory cells comprising a control gate terminal and an erase gate terminal (1701); and applying the bias voltage to a control gate terminal and an erase gate terminal of a selected memory cell in the array of memory cells while reading the selected memory cell (1702). In one example, operation 1701 is performed by CG-EG bias generation circuit 1300 of FIG. 13 and operation 1702 is performed by input block 1000 of FIG. 10 or CG-EG row driver 1400 of FIG. 14.

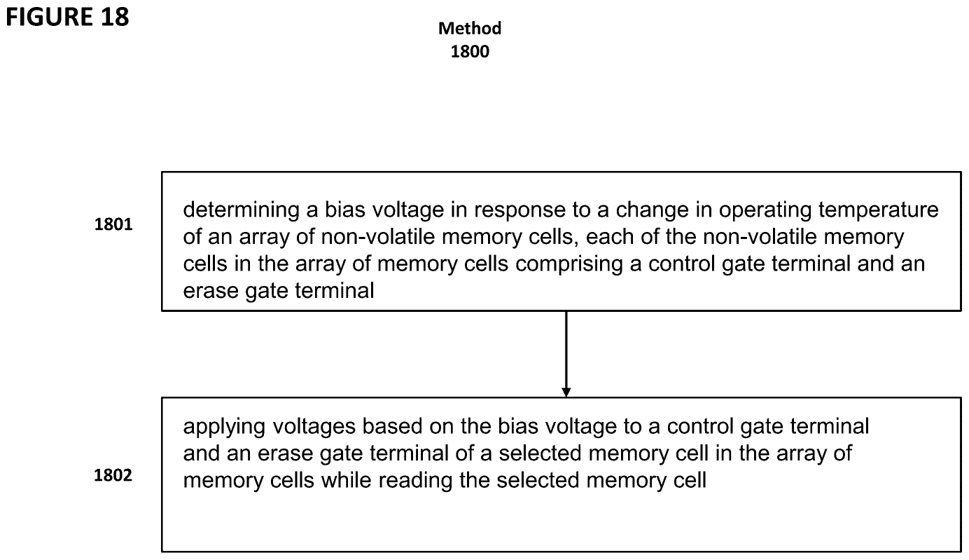

FIG. 18 depicts a method 1800 of compensating for changes in temperature. The method comprises determining a bias voltage in response to a change in operating temperature of an array of non-volatile memory cells, each of the non-volatile memory cells in the array of memory cells comprising a control gate terminal and an erase gate terminal (1801); and applying voltages based on the bias voltage (though row decoder) to a control gate terminal and an erase gate terminal of a selected memory cell in the array of memory cells while reading the selected memory cell (1802).

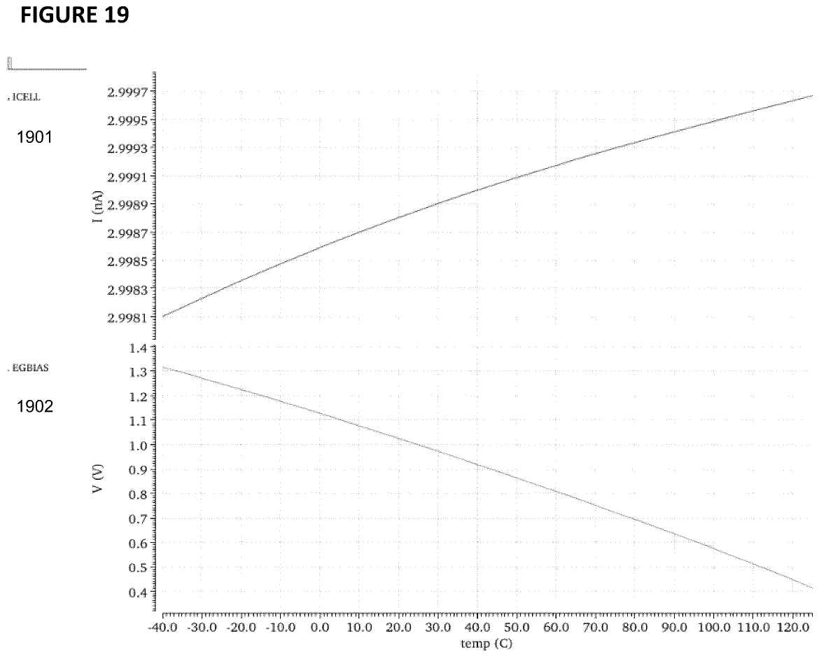

FIGS. 19-21 depict testing results showing the effect of applying CG-EG bias voltage 1304 of FIG. 13 to a control gate terminal and erase gate terminal of a selected memory cell as temperature changes.

FIG. 19 depicts graph 1901, which plots changes in read cell current through a selected memory cell as temperature changes, and graph 1902, which plots changes in CG-EG bias voltage 1304 as temperature changes. As can be seen the read cell current shows relatively small variation as the temperature changes, which is due to the application of CG-EG bias voltage 1304.

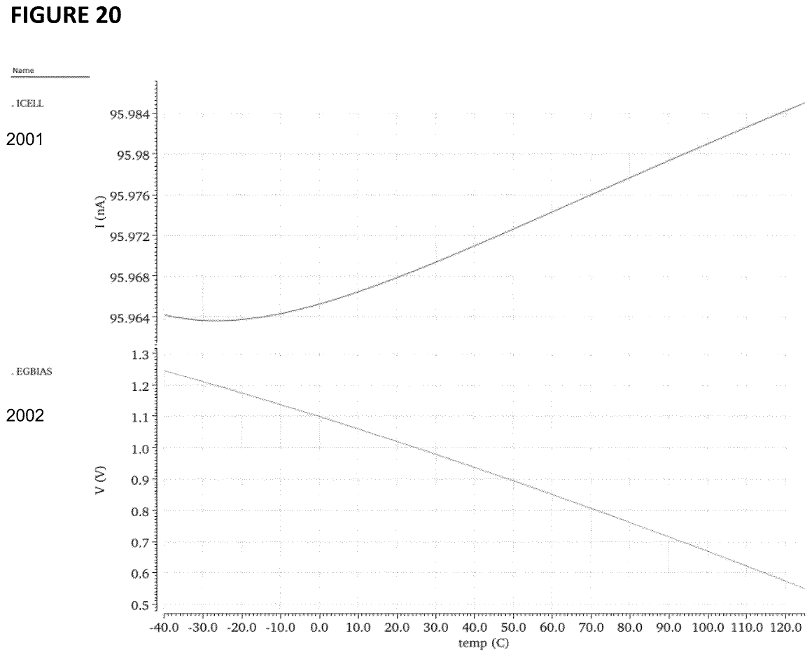

Similarly, FIG. 20 depicts graph 2001, which plots changes in read cell current through a selected memory cell as temperature changes, and graph 2002, which plots changes in CG-EG bias voltage 1304 as temperature changes. As can be seen the read cell current shows relatively small variation as the temperature changes, which is due to the application of CG-EG bias voltage 1304.

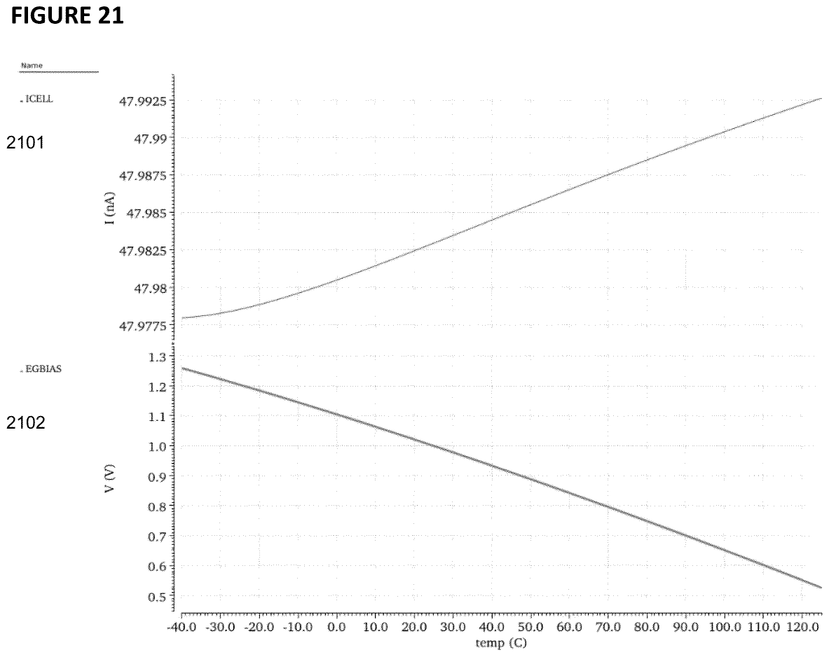

Similarly, FIG. 21 depicts graph 2101, which plots changes in read cell current through a selected memory cell as temperature changes, and graph 2102, which plots changes in CG-EG bias voltage 1304 as temperature changes. As can be seen the read cell current shows relatively small variation as the temperature changes, which is due to the application of CG-EG bias voltage 1304.

It should be noted that, as used herein, the terms “over” and “on” both inclusively include “directly on” (no intermediate materials, elements or space disposed therebetween) and “indirectly on” (intermediate materials, elements or space disposed therebetween). Likewise, the term “adjacent” includes “directly adjacent” (no intermediate materials, elements or space disposed therebetween) and “indirectly adjacent” (intermediate materials, elements or space disposed there between), “mounted to” includes “directly mounted to” (no intermediate materials, elements or space disposed there between) and “indirectly mounted to” (intermediate materials, elements or spaced disposed there between), and “electrically coupled” includes “directly electrically coupled to” (no intermediate materials or elements there between that electrically connect the elements together) and “indirectly electrically coupled to” (intermediate materials or elements there between that electrically connect the elements together). For example, forming an element “over a substrate” can include forming the element directly on the substrate with no intermediate materials/elements therebetween, as well as forming the element indirectly on the substrate with one or more intermediate materials/elements there between.

What is claimed is:

1. A method comprising:
determining a bias voltage in response to a change in operating temperature of an array of non-volatile memory cells, each of the non-volatile memory cells in the array of memory cells comprising a control gate terminal and an erase gate terminal; and
applying the bias voltage to a control gate terminal and an erase gate terminal of a selected memory cell in the array of memory cells while reading the selected memory cell.

2. The method of claim 1, wherein the non-volatile memory cells are split-gate flash memory cells.

3. A circuit to generate a control gate and erase gate bias voltage, comprising:
a reference memory cell comprising a control gate terminal, an erase gate terminal, and a bit line terminal;
a current digital-to-analog converter to generate a current in response to a digital input and to apply the current to the bit line terminal; and
an operational amplifier comprising an inverting terminal coupled to a bit line, a non-inverting terminal coupled to a reference voltage, and an output terminal providing a voltage to the control gate terminal and the erase gate terminal, wherein the voltage is output from the circuit as the control gate and erase gate bias voltage.

4. The circuit of claim 3, wherein the current digital-to-analog converter generates the current in response to a digital input.

5. The circuit of claim 3, further comprising a row driver comprising:
a PMOS transistor comprising a first terminal coupled to receive the control gate and erase gate bias voltage, a gate to receive a first control signal, and a second terminal;
a first NMOS transistor comprising a first terminal coupled to the second terminal of the PMOS transistor at a node, a gate to receive the first control signal, and a second terminal coupled to ground;
a second NMOS transistor comprising a first terminal coupled to the node, a gate to receive a second control signal, and a second terminal coupled to a control gate line of a row of cells in an array; and
a third NMOS transistor comprising a first terminal coupled to the node, a gate to receive the second control signal, and a second terminal coupled to an erase gate line of the row.

6. A method comprising:
determining a bias voltage in response to a change in operating temperature of an array of non-volatile memory cells, each of the non-volatile memory cells in the array of memory cells comprising a control gate terminal and an erase gate terminal; and
applying voltages based on the bias voltage to a control gate terminal and an erase gate terminal of a selected memory cell in the array of memory cells while reading the selected memory cell.

7. The method of claim 6, wherein the applying voltages is performed by a global digital-to-analog converter.

8. The method of claim 6, wherein the applying voltages is performed by a row decoder.

9. A method comprising:
conducting a bias current through a reference memory cell;
generating a bias voltage based on the bias current; and
applying the bias voltage to a control gate terminal and an erase gate terminal of a selected memory cell during a read operation.

10. The method of claim 9, wherein the applying comprises applying the bias voltage to a control gate terminal and an erase gate terminal of a selected memory cell.

11. The method of claim 9, wherein the applying is performed by a global digital-to-analog converter.

12. A method comprising:
deriving a bias voltage from a combined control gate and erase gate temperature compensated voltage; and
providing the bias voltage to control gate terminals and erase gate terminals of selected memory cells during a read operation.

13. The method of claim 12, wherein the providing is performed by a global digital-to-analog converter.

14. The method of claim 12, comprising coupling the control gate terminals and erase gate terminals of the selected memory cells to ground when the selected memory cells are not selected for a read operation.

15. A system comprising:
an array of non-volatile memory cells arranged into rows and columns, each of the non-volatile memory cells comprising a control gate terminal and an erase gate terminal, wherein the control gate terminal of each non-volatile memory cell in a row is coupled to a control gate line and the erase gate terminal of each non-volatile memory cell in a row is coupled to an erase gate line; and
a plurality of row circuits, each row circuit applying a voltage to a control gate line and an erase gate line coupled to a row of the array during a read operation of one or more non-volatile memory cells in the row.

16. The system of claim 15, wherein the voltage is generated by a global digital-to-analog converter shared by the plurality of row circuits.

17. The system of claim 16, wherein the global digital-to-analog converter generates the voltage based on a plurality of reference voltages.

18. The system of claim 17, wherein the plurality of reference voltages are generated in response to a combined control gate and erase gate bias voltage.

19. The system of claim 15, wherein each row circuit comprises a pulse generator to generate the voltage.

20. The system of claim 15, wherein each row circuit comprises a driver to generate the voltage.
